(19) United States
(12) Patent Application Publication
(10) Pub. No.: US 2026/0358379 A1
(43) Pub. Date: Nov. 12, 2026

(54) SYSTEMS AND METHODS FOR DUAL CURRENT SENSING FOR ELECTRIC VEHICLE

(71) Applicant: BorgWarner Inc., Auburn Hills, MI (US)

(72) Inventors: Elanchetchenni ADIAMAN, Sterling Heights, MI (US); Andreas MAYER, Clarkston, MI (US)

(73) Assignee: BorgWarner Inc., Auburn Hills, MI (US)

(21) Appl. No.: 19/205,035

(22) Filed: May 12, 2025

(51) Int. Cl. G01R 15/14; B60L 15/00; B60L 50/51; G01R 15/18; H02M 7/537

(52) U.S. Cl. CPC G01R 15/142; B60L 15/007; B60L 50/51; G01R 15/146; G01R 15/181; H02M 7/537; B60L 2210/44

(57) ABSTRACT

A system includes an inverter configured to convert DC power from a battery to AC power to drive a motor, wherein the inverter includes a current path, a shunt resistor configured to measure a current of the current path, and a first field effect coil configured to measure the current of the current path.

### TECHNICAL FIELD

Various embodiments of the present disclosure relate generally to inverters and, more particularly, to systems and methods for dual current sensing for inverters for electric vehicles.

### BACKGROUND

Inverters, such as those used to drive a motor in an electric vehicle, for example, are responsible for converting High Voltage Direct Current (HVDC) into Alternating Current (AC) to drive the motor. In an inverter, inaccurate measurement of current can compromise operation of the inverter.

The present disclosure is directed to overcoming one or more of these above-referenced challenges.

### SUMMARY OF THE DISCLOSURE

In some aspects, the techniques described herein relate to a system including: an inverter configured to convert DC power from a battery to AC power to drive a motor, wherein the inverter includes: a current path; a shunt resistor configured to measure a current of the current path; and a first field effect coil configured to measure the current of the current path.

In some aspects, the techniques described herein relate to a system, further including: a second field effect coil configured to measure the current of the current path.

In some aspects, the techniques described herein relate to a system, wherein the shunt resistor is surface mounted.

In some aspects, the techniques described herein relate to a system, wherein the shunt resistor is embedded on a printed circuit board.

In some aspects, the techniques described herein relate to a system, wherein the first field effect coil is a copper trace of a printed circuit board.

In some aspects, the techniques described herein relate to a system, further including: one or more bridge connector, wherein the one or more bridge connector connects to the current path and the one or more bridge connector connects to the shunt resistor.

In some aspects, the techniques described herein relate to a system, wherein the first field effect coil is inductively coupled with the current path.

In some aspects, the techniques described herein relate to a system, further including: one or more counter wound compensation coils configured to measure a second current of the current path.

In some aspects, the techniques described herein relate to a system, further including: the battery; and the motor, wherein the system is provided as an electric vehicle.

In some aspects, the techniques described herein relate to a system, further including: one or more controllers configured to control an operation of measuring the current of the current path.

In some aspects, the techniques described herein relate to a system for measuring current, the system including: a current path; a shunt resistor configured to measure the current of the current path; and a field effect coil configured to measure the current of the current path.

In some aspects, the techniques described herein relate to a system, further including a second field effect coil configured to measure the current of the current path.

In some aspects, the techniques described herein relate to a system, further including: a bridge connector, wherein the shunt resistor is a surface mounted shunt resistor electrically connected to the bridge connector.

In some aspects, the techniques described herein relate to a system, wherein the shunt resistor is an embedded shunt resistor and the field effect coil is a copper trace.

In some aspects, the techniques described herein relate to a system, further including a printed circuit board, wherein the current path, the shunt resistor, and the field effect coil are components electrically connected to the printed circuit board.

In some aspects, the techniques described herein relate to a system, wherein the shunt resistor is oriented horizontally with respect to the printed circuit board, and the field effect coil is oriented vertically with respect to the printed circuit board.

In some aspects, the techniques described herein relate to a system, wherein the shunt resistor is oriented vertically with respect to the printed circuit board, the field effect coil is oriented horizontally with respect to the printed circuit board.

In some aspects, the techniques described herein relate to a system including: a printed circuit board configured to measure current, wherein the printed circuit board includes: a current path; a first field effect coil configured to measure the current of the current path; a shunt resistor configured to measure the current of the current path; and a second field effect coil configured to measure the current of the current path after measurement by the first field effect coil and the shunt resistor.

In some aspects, the techniques described herein relate to a system, wherein the shunt resistor is an embedded shunt resistor oriented vertically with respect to the first field effect coil and the second field effect coil, and wherein the first field effect coil and the second field effect coil are oriented horizontally with respect to the embedded shunt resistor.

In some aspects, the techniques described herein relate to a system, further including a first layer of the printed circuit board, a second layer of the printed circuit board, a third layer of the printed circuit board, and a fourth layer of the printed circuit board, wherein the first layer of the printed circuit board and the fourth layer of the printed circuit board are electrically connected to the shunt resistor, and the second layer of the printed circuit board and the third layer of the printed circuit board are inductively coupled with the shunt resistor.

Additional objects and advantages of the disclosed embodiments will be set forth in part in the description that follows, and in part will be apparent from the description, or may be learned by practice of the disclosed embodiments. The objects and advantages of the disclosed embodiments will be realized and attained by means of the elements and combinations particularly pointed out in the appended claims.

It is to be understood that both the foregoing general description and the following detailed description are exemplary and explanatory only and are not restrictive of the disclosed embodiments, as claimed.

### BRIEF DESCRIPTION OF THE DRAWINGS

The accompanying drawings, which are incorporated in and constitute a part of this specification, illustrate various exemplary embodiments and together with the description, serve to explain the principles of the disclosed embodiments.

FIG. 1 depicts an exemplary system infrastructure for a vehicle including an inverter, according to one or more embodiments.

FIG. 2 depicts an exemplary system infrastructure for a power converter, according to one or more embodiments.

FIG. 3 depicts an exemplary system infrastructure for a controller, according to one or more embodiments.

FIG. 4 depicts an exemplary operation of dual current measurement with three phases, according to one or more embodiments.

FIG. 5 depicts an exemplary system infrastructure for counter wound compensation, according to one or more embodiments.

FIG. 6 depicts an exemplary system infrastructure for phase current sensing with dual methods, including a shunt resistor with bridge connector and field effect coils in the PCB copper layer, according to one or more embodiments.

FIG. 7 depicts an exemplary system infrastructure for horizontal embedded shunt resistor with vertical current transformer loop, in a top view, according to one or more embodiments.

FIG. 8 depicts an exemplary system infrastructure for horizontal embedded shunt resistor with vertical current transformer loop, in a first sectional view, according to one or more embodiments.

FIG. 9 depicts an exemplary system infrastructure for horizontal embedded shunt resistor with vertical current transformer loop, in a second sectional view, according to one or more embodiments.

FIG. 10 depicts an exemplary system infrastructure for vertical embedded shunt resistor with horizontal current transformer loops, according to one or more embodiments.

### DETAILED DESCRIPTION OF EMBODIMENTS

Both the foregoing general description and the following detailed description are exemplary and explanatory only and are not restrictive of the features, as claimed. As used herein, the terms “comprises,” “comprising,” “has,” “having,” “includes,” “including,” or other variations thereof, are intended to cover a non-exclusive inclusion such that a process, method, article, or apparatus that comprises a list of elements does not include only those elements, but may include other elements not expressly listed or inherent to such a process, method, article, or apparatus. In this disclosure, unless stated otherwise, relative terms, such as, for example, “about,” “substantially,” and “approximately” are used to indicate a possible variation of ±10% in the stated value. In this disclosure, unless stated otherwise, any numeric value may include a possible variation of ±10% in the stated value.

The terminology used below may be interpreted in its broadest reasonable manner, even though it is being used in conjunction with a detailed description of certain specific examples of the present disclosure. Indeed, certain terms may even be emphasized below; however, any terminology intended to be interpreted in any restricted manner will be overtly and specifically defined as such in this Detailed Description section. For example, in the context of the disclosure, switching devices may be described as switches or devices, but may refer to any device for controlling the flow of power in an electrical circuit. For example, switches may be metal–oxide–semiconductor field-effect transistors (MOSFETs), bipolar junction transistors (BJTs), insulated-gate bipolar transistors (IGBTs), or relays, for example, or any combination thereof, but are not limited thereto.

Various embodiments of the present disclosure relate generally to inverters and, more particularly, to systems and methods for dual current sensing for inverters for electric vehicles.

Inverters, such as those used to drive a motor in an electric vehicle, for example, are responsible for converting High Voltage Direct Current (HVDC) into Alternating Current (AC) to drive the motor. A three phase inverter may include a bridge with six power device switches (for example, power transistors such as IGBT or MOSFET) that are controlled by Pulse Width Modulation (PWM) signals generated by a controller. An inverter may include three half-H bridge switches to control the phase voltage, upper and lower gate drivers to control the switches, a PWM controller, and glue logic between the PWM controller and the gate drivers. The PWM controller may generate signals to define the intended states of the system. The gate drivers may send the signals from the PWM controller to the half-H bridge switches. The half-H bridge switches may drive the phase voltage. Six phase (or other phase) inverters, chargers, DC-DC converters, and/or multi-level inverters are not excluded from this concept and will follow similar principles. The present disclosure refers to an inverter as an example embodiment of a power converter. Power converters may include chargers, inverters, or DC-DC converters, for example.

Electric vehicles, energy storage systems, and backup generators, for example, convert electric power from one form to another. Additionally, an on-board charger for a vehicle, for example, may have a dual purpose. The on-board charger may be a bi-directional system that converts AC voltage to DC voltage in a charging mode (grid-to-battery) and DC voltage to AC voltage in a discharge or inverter mode (battery-to-grid). The charging mode may convert the grid AC into DC voltage to charge the vehicle high voltage (HV) battery, and the discharge or inverter mode may convert the HV battery DC voltage into AC voltage that may be supplied to a load of the grid line voltage, be supplied as a backup generator to power a house when the grid is down, or as an inverter to supply voltage to vehicle AC outlets, for example.

Traction inverter AC phase current sensing function may include a high functional safety rating in accordance with automotive safety integrity level (e.g. ASIL D). To achieve such high rating, redundancies and diagnostics in current sensing may be mandatory.

One or more embodiments may provide a dual method current measurement solution for AC current sensing in traction inverters. One or more embodiments may include a first measurement method, which may include a PCB based current sensor with a shunt resistance either surface mount or embedded. One or more embodiments may include a second measurement method, which may include, instead of implementing a Flex-PCB based Rogowski coil (flex printed circuit board based Rogowski coil), the coil(s) may be designed with the PCB layers/traces, which may effectively create a field effect based second measurement method.

For some 3-phase inverter-motor system implementations, current sensing may include current sensing on each of the phase legs with three current sensors, each sensor with two sensing elements (e.g. hall field effect), providing one cross reference point (diagnostic) for each sensor.

One or more embodiments may provide implementation of dual measurement method, which may provide or enable the measurement of just two phases (e.g., phase A and C) while maintaining high signal and measurement integrity having a total of two current sensors, each sensor with three sensing elements (one shunt + two field effect coils), providing three cross reference points (diagnostics) for each sensor.

One or more embodiments may provide use of PCB copper traces for the field effect-based measurement, which may be beneficial for traction inverter applications, and may reduce cost and increase reliability. Additionally, the PCB based solution may offer a high level of customization. For example, one or more embodiments may provide that shunt resistance may be configured for specific requirements and the effective flux induced in the coil may be configured or refined, by controlling or designing the number of turns, copper trace width, via size and via position, and copper layer thickness.

One or more embodiments may provide highly beneficial results in PCB based (power board) inverters such as for discrete and embedded FET, where elimination or removal of busbars in the inverter may provide added cost and manufacturing/assembly benefit.

One or more embodiments may provide high design flexibility offered by implementing the field effect coil using PCB layers or PCB traces, which may provide that designing compensation coils (secondary) along with the main coils (primary) may be possible. This feature may further improve the accuracy of obtained current measurements.

One or more embodiments may provide a method or system including surface mount resistor with bridge connector. One or more embodiments may provide a method or system including horizontal embedded shunt resistor with vertical current transformer loop horizontal embedded shunt and vertical current transformer trace. One or more embodiments may include a method or system including a vertical embedded shunt resistor with horizontal current transformer loop.

One or more embodiments may provide an accurate shunt based current measurement systems and methods offering a bandwidth up to 1 GHz. One or more embodiments may provide a shunt resistance value provided as a single variable input for current measurement computation along with temperature compensation. One or more embodiments may provide accurate current measurements at both stable temperatures and with temperature variations.

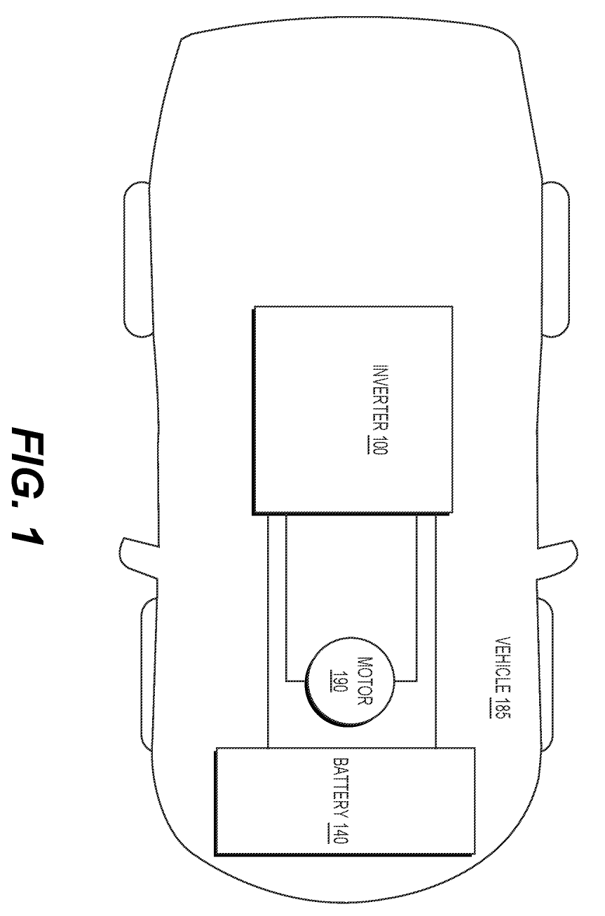

FIG. 1 depicts an exemplary system infrastructure for a vehicle including an inverter, according to one or more embodiments. The inverter 100 may be a power converter. The inverter 100 may be a combined inverter and converter. Alternatively, the inverter may be an inverter without a converter. In the context of this disclosure, a battery charger, the inverter, the converter, or any combination thereof may be referred to as inverter 100. Electric vehicle 185 may include inverter 100, motor 190, and battery 140. Inverter 100 may include components to receive electrical power from an external source and output electrical power to charge battery 140 of electric vehicle 185. Inverter 100 may convert DC power from battery 140 in electric vehicle 185 to AC power, to drive motor 190 of the electric vehicle 185, for example, but the embodiments are not limited thereto. For example, inverter 100 may include components to receive electrical power from an external source and output electrical power to charge battery 140 without motor 190 connected to inverter 100. Inverter 100 may convert DC power from battery 140 in electric vehicle 185 to AC power, to drive AC components other than motor 190 of the electric vehicle 185. Inverter 100 may be bidirectional, and may convert DC power to AC power, or convert AC power to DC power, such as during regenerative braking, for example. Inverter 100 may be a three-phase inverter, a single-phase inverter, or a multi-phase inverter.

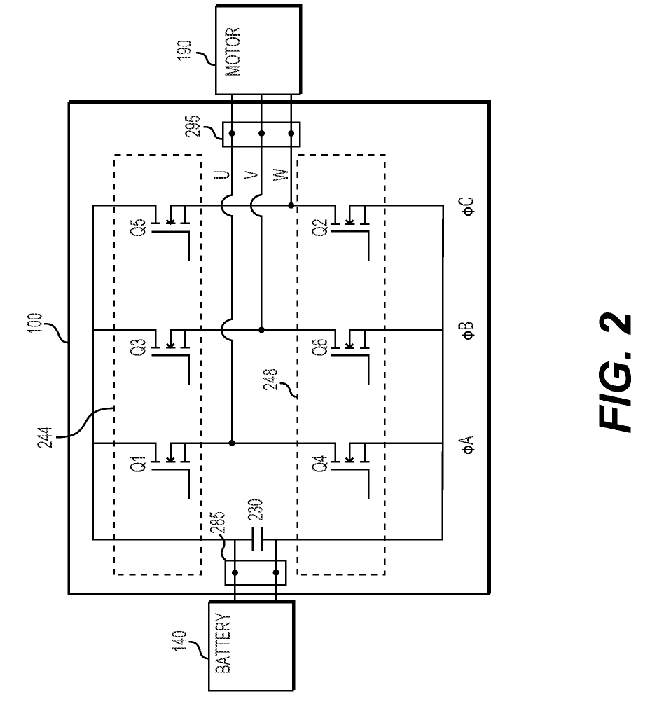

FIG. 2 depicts an exemplary system infrastructure for a power converter, according to one or more embodiments. Inverter 100 may be used to convert DC power from a battery in electric vehicle 185 to AC power, to drive motor 190 of electric vehicle 185, for example, but embodiments are not limited thereto. Additionally, inverter 100 may be bidirectional, and used to convert DC power to AC power, or to convert AC power to DC power.

Inverter 100 may be connected to battery 140 and motor 190. Inverter 100 may include upper phase switches 244 and lower phase switches 248. A first phase (ΦA) may include switches Q1 and Q4, a second phase (ΦB) may include switches Q3 and Q6, and a third phase (ΦC) may include switches Q5 and Q2. Upper phase switches 244 may include first phase switch Q1, second phase switch Q3, and third phase switch Q5. Lower phase switches 248 may include first phase switch Q4, second phase switch Q6, and third phase switch Q2. Switches Q1-Q6 may be metal–oxide–semiconductor field-effect transistors (MOSFET), for example, but embodiments are not limited thereto.

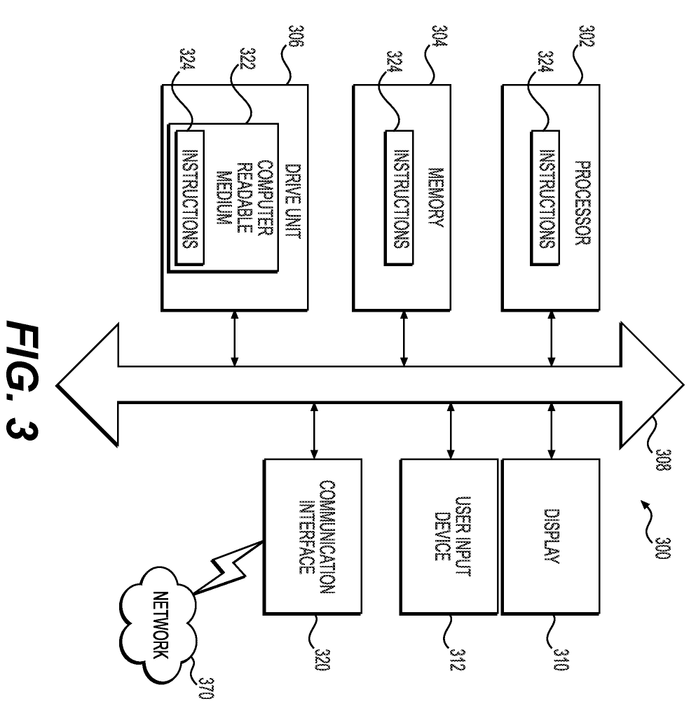

Upper phase switches 244 and lower phase switches 248 may be driven by a pulse width modulated (PWM) signal generated by controller 300 (e.g., see FIG. 3) to convert DC power delivered via the set of input terminals 285 at bulk capacitor 230 to three phase AC power at outputs U, V, and W (correlating with phases A, B, and C, respectively) via the set of output terminals 295 to motor 190. Additionally, although FIG. 2 depicts a three-phase inverter, the disclosure is not limited thereto and may include single phase or multi-phase or multi-level inverters.

FIG. 3 depicts an exemplary system infrastructure for a controller, according to one or more embodiments. Controller 300 may include one or more controllers.

The controller 300 may include a set of instructions that can be executed to cause the controller 300 to perform any one or more of the methods or computer based functions disclosed herein. The controller 300 may operate as a standalone device or may be connected, e.g., using a network, to other computer systems or peripheral devices.

In a networked deployment, the controller 300 may operate in the capacity of a server or as a client in a server-client user network environment, or as a peer computer system in a peer-to-peer (or distributed) network environment. The controller 300 can also be implemented as or incorporated into various devices, such as a power converter, a personal computer (PC), a tablet PC, a set-top box (STB), a personal digital assistant (PDA), a mobile device, a palmtop computer, a laptop computer, a desktop computer, a communications device, a wireless telephone, a land-line telephone, a control system, a camera, a scanner, a facsimile machine, a printer, a pager, a personal trusted device, a web appliance, a network router, switch or bridge, or any other machine capable of executing a set of instructions (sequential or otherwise) that specify actions to be taken by that machine. In a particular implementation, the controller 300 can be implemented using electronic devices that provide voice, video, or data communication. Further, while the controller 300 is illustrated as a single system, the term “system” shall also be taken to include any collection of systems or sub-systems that individually or jointly execute a set, or multiple sets, of instructions to perform one or more computer functions.

As depicted in FIG. 3, the controller 300 may include a processor 302, e.g., a central processing unit (CPU), a graphics processing unit (GPU), or both. The processor 302 may be a component in a variety of systems. The processor 302 may be one or more general processors, digital signal processors, application specific integrated circuits, field programmable gate arrays, servers, networks, digital circuits, analog circuits, combinations thereof, or other now known or later developed devices for analyzing and processing data. The processor 302 may implement a software program, such as code generated manually (i.e., programmed).

The controller 300 may include a memory 304 that can communicate via a bus 308. The memory 304 may be a main memory, a static memory, or a dynamic memory. The memory 304 may include, but is not limited to computer readable storage media such as various types of volatile and non-volatile storage media, including but not limited to random access memory, read-only memory, programmable read-only memory, electrically programmable read-only memory, electrically erasable read-only memory, flash memory, magnetic tape or disk, optical media and the like. In one implementation, the memory 304 includes a cache or random-access memory for the processor 302. In alternative implementations, the memory 304 is separate from the processor 302, such as a cache memory of a processor, the system memory, or other memory. The memory 304 may be an external storage device or database for storing data. Examples include a hard drive, compact disc (“CD”), digital video disc (“DVD”), memory card, memory stick, floppy disc, universal serial bus (“USB”) memory device, or any other device operative to store data. The memory 304 is operable to store instructions executable by the processor 302. The functions, acts or tasks illustrated in the figures or described herein may be performed by the processor 302 executing the instructions stored in the memory 304. The functions, acts or tasks are independent of the particular type of instructions set, storage media, processor or processing strategy and may be performed by software, hardware, integrated circuits, firm-ware, micro-code and the like, operating alone or in combination. Likewise, processing strategies may include multiprocessing, multitasking, parallel processing and the like.

As depicted, the controller 300 may further include a display 310, such as a liquid crystal display (LCD), an organic light emitting diode (OLED), a flat panel display, a solid-state display, a cathode ray tube (CRT), a projector, a printer or other now known or later developed display device for outputting determined information. The display 310 may act as an interface for the user to see the functioning of the processor 302, or specifically as an interface with the software stored in the memory 304 or in the drive unit 306.

Additionally or alternatively, the controller 300 may include an input device 312 configured to allow a user to interact with any of the components of controller 300. The input device 312 may be a number pad, a keyboard, or a cursor control device, such as a mouse, or a joystick, touch screen display, remote control, or any other device operative to interact with the controller 300.

The controller 300 may also or alternatively include drive unit 306 implemented as a disk or optical drive. The drive unit 306 may include a computer-readable medium 322 in which one or more sets of instructions 324, e.g. software, can be embedded. Further, the instructions 324 may embody one or more of the methods or logic as described herein. The instructions 324 may reside completely or partially within the memory 304 and/or within the processor 302 during execution by the controller 300. The memory 304 and the processor 302 also may include computer-readable media as discussed above.

In some systems, a computer-readable medium 322 includes instructions 324 or receives and executes instructions 324 responsive to a propagated signal so that a device connected to a network 370 can communicate voice, video, audio, images, or any other data over the network 370. Further, the instructions 324 may be transmitted or received over the network 370 via a communication port or interface 320, and/or using a bus 308. The communication port or interface 320 may be a part of the processor 302 or may be a separate component. The communication port or interface 320 may be created in software or may be a physical connection in hardware. The communication port or interface 320 may be configured to connect with a network 370, external media, the display 310, or any other components in controller 300, or combinations thereof. The connection with the network 370 may be a physical connection, such as a wired Ethernet connection or may be established wirelessly as discussed below. Likewise, the additional connections with other components of the controller 300 may be physical connections or may be established wirelessly. The network 370 may alternatively be directly connected to a bus 308.

While the computer-readable medium 322 is depicted to be a single medium, the term "computer-readable medium" may include a single medium or multiple media, such as a centralized or distributed database, and/or associated caches and servers that store one or more sets of instructions. The term "computer-readable medium" may also include any medium that is capable of storing, encoding, or carrying a set of instructions for execution by a processor or that cause a computer system to perform any one or more of the methods or operations disclosed herein. The computer-readable medium 322 may be non-transitory, and may be tangible.

The computer-readable medium 322 can include a solid-state memory such as a memory card or other package that houses one or more non-volatile read-only memories. The computer-readable medium 322 can be a random-access memory or other volatile re-writable memory. Additionally or alternatively, the computer-readable medium 322 can include a magneto-optical or optical medium, such as a disk or tapes or other storage device to capture carrier wave signals such as a signal communicated over a transmission medium. A digital file attachment to an e-mail or other self-contained information archive or set of archives may be considered a distribution medium that is a tangible storage medium. Accordingly, the disclosure is considered to include any one or more of a computer-readable medium or a distribution medium and other equivalents and successor media, in which data or instructions may be stored.

In an alternative implementation, dedicated hardware implementations, such as application specific integrated circuits, programmable logic arrays and other hardware devices, can be constructed to implement one or more of the methods described herein. Applications that may include the apparatus and systems of various implementations can broadly include a variety of electronic and computer systems. One or more implementations described herein may implement functions using two or more specific interconnected hardware modules or devices with related control and data signals that can be communicated between and through the modules, or as portions of an application-specific integrated circuit. Accordingly, the present system encompasses software, firmware, and hardware implementations.

The controller 300 may be connected to a network 370. The network 370 may define one or more networks including wired or wireless networks. The wireless network may be a cellular telephone network, an 802.11, 802.16, 802.20, or WiMAX network. Further, such networks may include a public network, such as the Internet, a private network, such as an intranet, or combinations thereof, and may utilize a variety of networking protocols now available or later developed including, but not limited to TCP/IP based networking protocols. The network 370 may include wide area networks (WAN), such as the Internet, local area networks (LAN), campus area networks, metropolitan area networks, a direct connection such as through a Universal Serial Bus (USB) port, or any other networks that may allow for data communication. The network 370 may be configured to couple one computing device to another computing device to enable communication of data between the devices. The network 370 may generally be enabled to employ any form of machine-readable media for communicating information from one device to another. The network 370 may include communication methods by which information may travel between computing devices. The network 370 may be divided into sub-networks. The sub-networks may allow access to all of the other components connected thereto or the sub-networks may restrict access between the components. The network 370 may be regarded as a public or private network connection and may include, for example, a virtual private network or an encryption or other security mechanism employed over the public Internet, or the like.

In accordance with various implementations of the present disclosure, the methods described herein may be implemented by software programs executable by a computer system. Further, in an exemplary, non-limited implementation, implementations can include distributed processing, component or object distributed processing, and parallel processing. Alternatively, virtual computer system processing can be constructed to implement one or more of the methods or functionality as described herein.

Although the present specification describes components and functions that may be implemented in particular implementations with reference to particular standards and protocols, the disclosure is not limited to such standards and protocols. For example, standards for Internet and other packet switched network transmission (e.g., TCP/IP, UDP/IP, HTML, HTTP) represent examples of the state of the art. Such standards are periodically superseded by faster or more efficient equivalents having essentially the same functions. Accordingly, replacement standards and protocols having the same or similar functions as those disclosed herein are considered equivalents thereof.

It will be understood that the operations of methods discussed are performed in one embodiment by an appropriate processor (or processors) of a processing (i.e., computer) system executing instructions (computer-readable code) stored in storage. It will also be understood that the disclosure is not limited to any particular implementation or programming technique and that the disclosure may be implemented using any appropriate techniques for implementing the functionality described herein. The disclosure is not limited to any particular programming language or operating system.

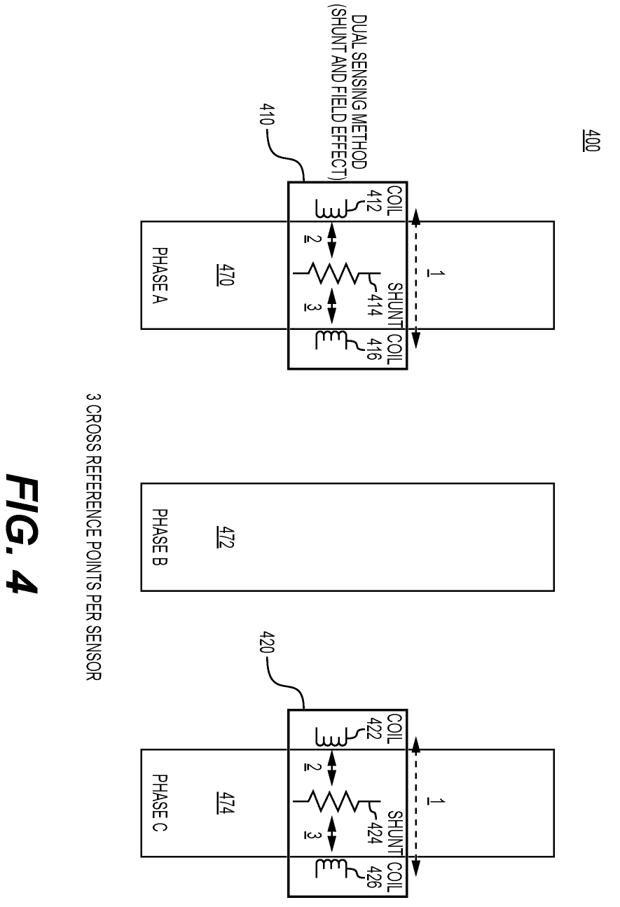

FIG. 4 depicts an exemplary operation of dual current measurement with three phases, according to one or more embodiments. System 400 may include sensor 410, sensor 420, and three-phase power including phase A 470, phase B 472, and phase C 474. Sensor 410 and sensor 420 may include implementation of dual measurement method. Sensor 410 may include shunt resistor 414, first field effect coil 412, and second field effect coil 416. Sensor 420 may include shunt resistor 424, first field effect coil 422, and second field effect coil 426. System 400 thus may include implementation of dual measurement method with a total of two sensors, each sensor which may have three sensing elements, providing three cross reference points or diagnostics for each sensor. System 400 does not include a third sensor for a third phase (e.g., phase B 472).

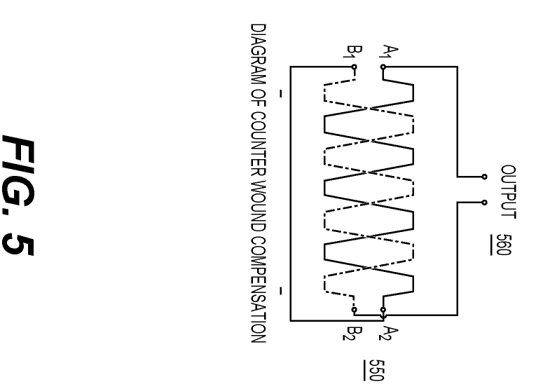

FIG. 5 depicts an exemplary system infrastructure for counter wound compensation coils, according to one or more embodiments. A coil may be counter wound and provide counter wound compensation implementation 550 providing output 560.

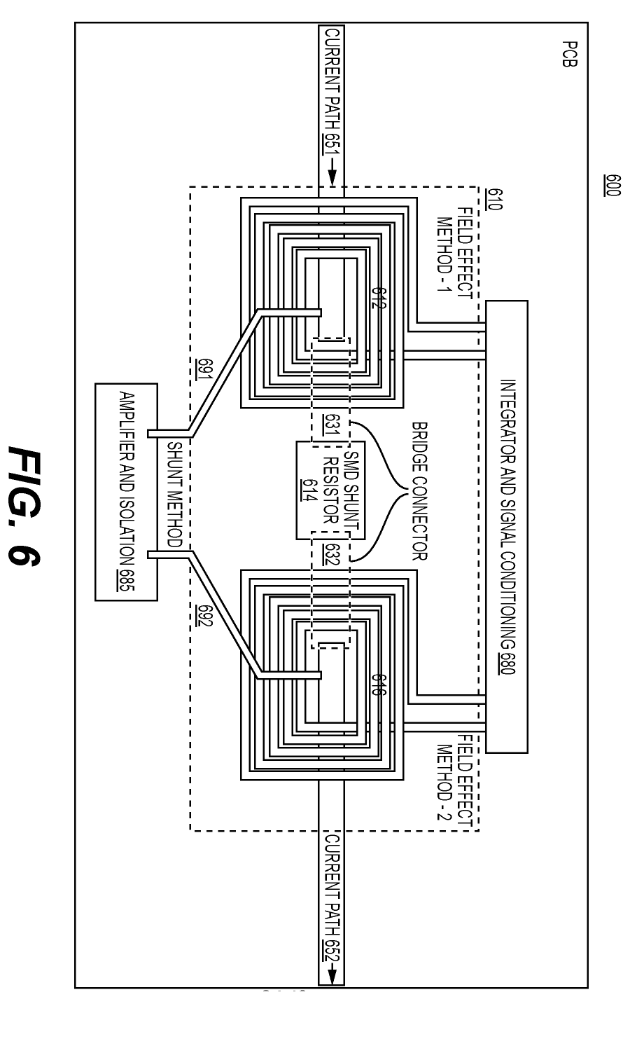

FIG. 6 depicts an exemplary system infrastructure for phase current sensing with dual methods, including a shunt resistor with bridge connector and field effect coils in the PCB copper layer, according to one or more embodiments. Printed circuit board 600 may include first current path 651, sensor 610, second current path 652, integrator and signal conditioning 680, and amplifier and isolation 685. Sensor 610 may include first field effect coil 612, shunt resistor 614, second field effect coil 616, first bridge connector 631, and second bridge connector 632. Sensor 610 may include one or more bridge connectors. Shunt resistor 614 may be a surface mounted shunt resistor. Shunt resistor 614 may be an embedded shunt resistor. First current path 651 may pass through first field effect coil 612, first field effect coil 612 may surround first current path 651 and not touch first current path 651. First current path 651 may electrically connect with shunt resistor 614 by first bridge connector 631. Second current path 652 may electrically connect to shunt resistor 614 by second bridge connector 632. Amplifier and isolation 685 may electrically connect with first current path 651 by first leg 691. Amplifier and isolation 685 may electrically connect with second current path 652 by second leg 692. Integrator and signal conditioning 680 may electrically connect to first field effect coil 612 and second field effect coil 616. Shunt resistor 614 may be a surface mounted shunt resistor on a printed circuit board (e.g., printed circuit board 600). First field effect coil 612 may be inductively coupled with first current path 651 and second field effect coil 616 may be inductively coupled with second current path 652.

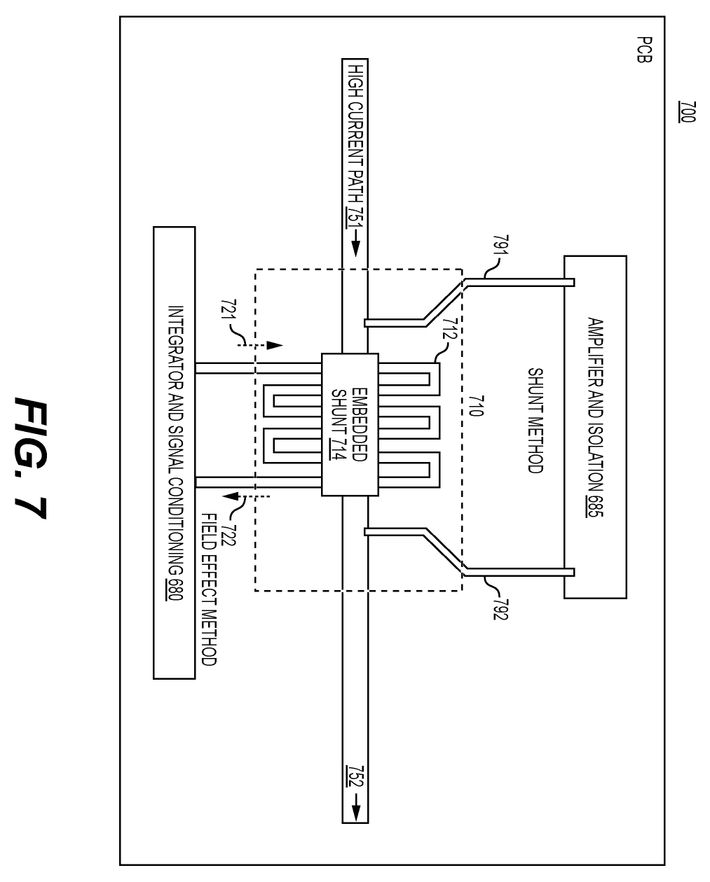

FIG. 7 depicts an exemplary system infrastructure for horizontal embedded shunt resistor with vertical current transformer loop, in a top view, according to one or more embodiments. Printed circuit board 700 may include first current path 751, sensor 710, second current path 752, integrator and signal conditioning 680, and amplifier and isolation 685. Sensor 710 may include field effect coil 712 and embedded shunt resistor 714. Embedded shunt resistor 714 may be oriented horizontally with respect to the printed circuit board 700, and field effect coil 712, which may include vertical current transformer trace, may be oriented vertically with respect to the printed circuit board 700. Field effect coil 712 may include a main coil 721 and a compensation coil 722. Main coil 721 and compensation coil 722 may be counter wound. Field effect coil 712 may include two field effect coils and may include a first field effect coil and second field effect coil that are not counter wound. For example, field effect coil 712 may include a field effect coil designed with printed circuit board layers. Field effect coil 712 may include a field effect coil designed with printed circuit board traces. Multiple PCB layers may be utilized to design one or more vertical field effect coils. To achieve the required field strength for current sensing, the trace shape or width of each layer may be customized. “Vias” (connecting each layer) may also be customized. Via size, number of vias, and arrangement of vias may be modified.

First current path 751 may be a high current path and may be electrically connected to embedded shunt resistor 714. Second current path 752 may be electrically connected to embedded shunt resistor 714. Field effect coil 712 may include a vertical current transformer loop. Field effect coil 712 may surround first current path 751 without contacting first current path 751. Field effect coil 712 may surround second current path 752 without touching second current path 752. For example, field effect coil 712 may include main coil 721 surrounding first current path 751 and compensation coil surrounding second current path 752.

Field effect coil 712 may electrically connect to integrator and signal conditioning 680. Amplifier and isolation 685 may be connected to first current path 751 with first leg 791 and may be connected to second current path 752 with second leg 792.

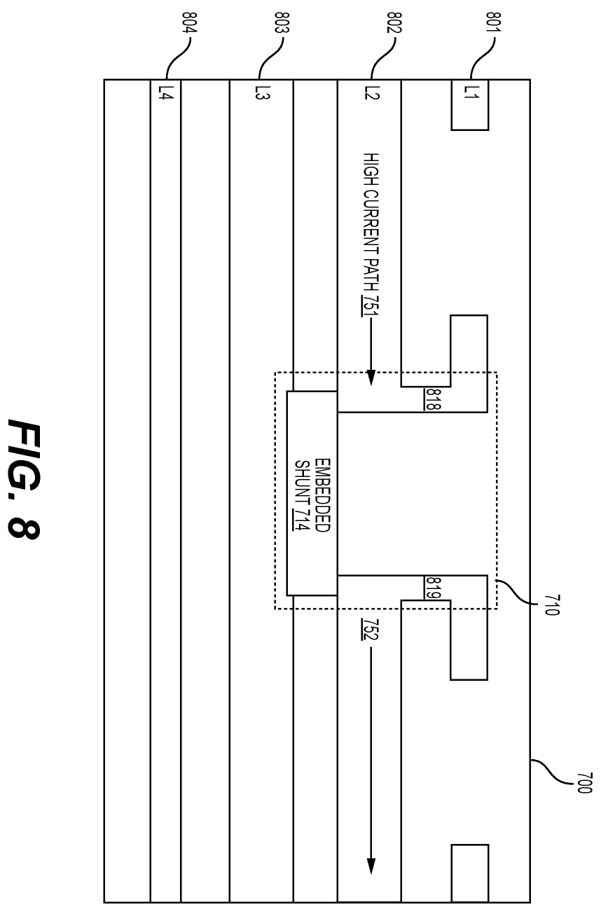

FIG. 8 depicts an exemplary system infrastructure for horizontal embedded shunt resistor with vertical current transformer loop, in a first sectional view, according to one or more embodiments. Printed circuit board 700 may include first layer 801, second layer 802, third layer 803, fourth layer 804, first current path 751, second current path 752, first via 818, second via 819, and sensor 710. Sensor 710 may include embedded shunt resistor 714, first via 818, and second via 819. The first sectional view of FIG. 8 may depict printed circuit board 700 viewed from a first angle, for example, zero degrees. For example, sensor 710 may include field effect coil 712. Furthermore, field effect coil 712 may include first via 818 and second via 819.

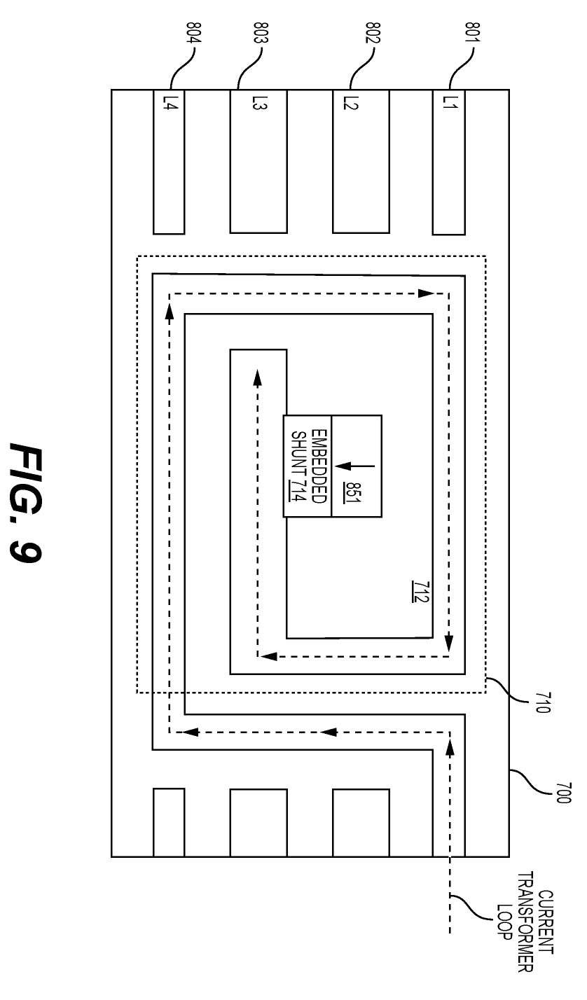

FIG. 9 depicts an exemplary system infrastructure for horizontal embedded shunt resistor with vertical current transformer loop, in a second sectional view, according to one or more embodiments. Printed circuit board 700 may include first layer 801, second layer 802, third layer 803, fourth layer 804, sensor 710, and high current path 851. Sensor 710 may include field effect coil 712 and embedded shunt resistor 714. Field effect coil 712 may include, for example, current transformer loop. High current path 851 may include first current path 751 or second current path 752. High current path 851 may include first current path 751 and second current path 752. The second sectional view of FIG. 9 may depict printed circuit board 700 viewed from a second angle, for example, ninety degrees from first sectional view. For example, high current path 851 may include first current path 751 or second current path 752. High current path 851 may include first current path 751 and second current path 752.

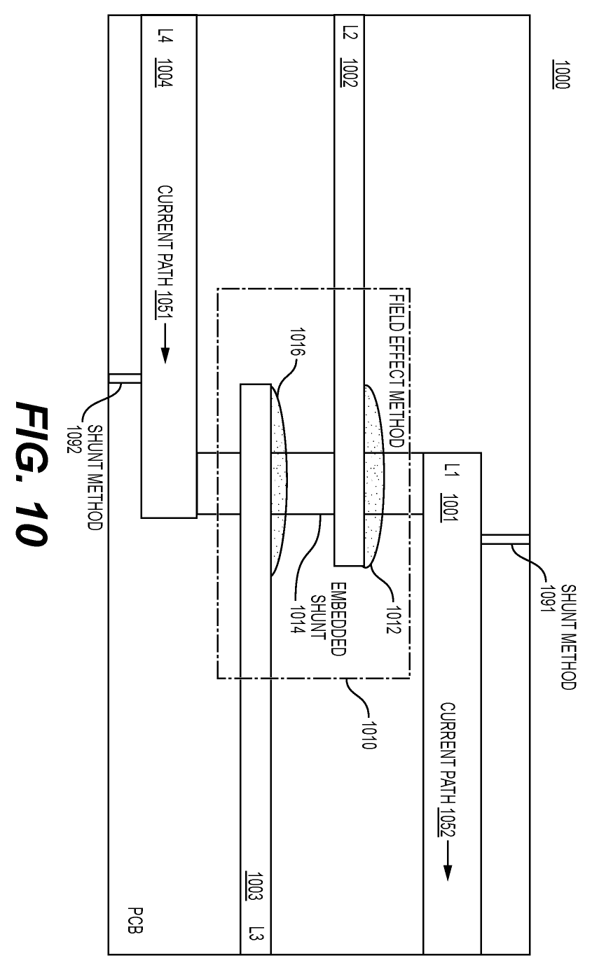

FIG. 10 depicts an exemplary system infrastructure for vertical embedded shunt resistor with horizontal current transformer loops, according to one or more embodiments. Printed circuit board 1000 may include first layer 1001, second layer 1002, third layer 1003, fourth layer 1004, shunt method leg 1091, shunt method leg 1092, and sensor 1010. Sensor 1010 may include first field effect coil 1012, embedded shunt resistor 1014, and second field effect coil 1016. First field effect coil 1012 may include printed circuit board layer or trace. For example, first field effect coil 1012 may include second layer 1002. First field effect coil 1012 may provide a first field effect current measurement. Second field effect coil 1016 may include printed circuit board layer or trace. Second field effect coil 1016 may include third layer 1003. Second field effect coil 1016 may provide a second field effect current measurement. Shunt method leg 1092 may be electrically connected to first current path 1051 and may be electrically connected to fourth layer 1004. Shunt method leg 1091 may be electrically connected to second current path 1052 and may be electrically connected to first layer 1001. Shunt method leg 1091 and shunt method leg 1092 may provide current measurements. Embedded shunt resistor 1014 may be oriented vertically with respect to the printed circuit board 1000. First field effect coil 1012 and second field effect coil 1016 may be oriented horizontally with respect to the printed circuit board 1000.

One or more embodiments may provide dual current measurement systems and methods that may reduce costs in traction inverter applications. One or more embodiments may provide dual current measurement systems and methods that may increase reliability of current measurement in traction inverter applications. One or more embodiments may provide printed circuit board based dual current measurement, and may provide a high level of customization, where shunt resistance may be configured for specific requirements and the effective flux induced in a coil can be configured by controlling or designing the number of turns, copper trace width, via size, via separation, and copper layer thickness.

Other embodiments of the disclosure will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A system comprising:
an inverter configured to convert DC power from a battery to AC power to drive a motor, wherein the inverter includes:
a current path;
a shunt resistor configured to measure a current of the current path; and
a first field effect coil configured to measure the current of the current path.

2. The system of claim 1, further comprising:
a second field effect coil configured to measure the current of the current path.

3. The system of claim 1, wherein the shunt resistor is surface mounted.

4. The system of claim 1, wherein the shunt resistor is embedded on a printed circuit board.

5. The system of claim 1, wherein the first field effect coil is a copper trace of a printed circuit board.

6. The system of claim 1, further comprising:
one or more bridge connector, wherein the one or more bridge connector connects to the current path and the one or more bridge connector connects to the shunt resistor.

7. The system of claim 1, wherein the first field effect coil is inductively coupled with the current path.

8. The system of claim 1, further comprising:
one or more counter wound compensation coils configured to measure a second current of the current path.

9. The system of claim 1, further comprising:
the battery; and
the motor,
wherein the system is provided as an electric vehicle.

10. The system of claim 1, further comprising:
one or more controllers configured to control an operation of measuring the current of the current path.

11. A system for measuring current, the system including:
a current path;
a shunt resistor configured to measure the current of the current path; and
a field effect coil configured to measure the current of the current path.

12. The system of claim 11, further comprising a second field effect coil configured to measure the current of the current path.

13. The system of claim 11, further comprising:
a bridge connector, wherein the shunt resistor is a surface mounted shunt resistor electrically connected to the bridge connector.

14. The system of claim 11, wherein the shunt resistor is an embedded shunt resistor and the field effect coil is a copper trace.

15. The system of claim 11, further comprising a printed circuit board, wherein the current path, the shunt resistor, and the field effect coil are components electrically connected to the printed circuit board.

16. The system of claim 15, wherein the shunt resistor is oriented horizontally with respect to the printed circuit board, and the field effect coil is oriented vertically with respect to the printed circuit board.

17. The system of claim 15, wherein the shunt resistor is oriented vertically with respect to the printed circuit board, the field effect coil is oriented horizontally with respect to the printed circuit board.

18. A system comprising:
a printed circuit board configured to measure current, wherein the printed circuit board includes:
a current path;
a first field effect coil configured to measure the current of the current path;
a shunt resistor configured to measure the current of the current path; and
a second field effect coil configured to measure the current of the current path after measurement by the first field effect coil and the shunt resistor.

19. The system of claim 18, wherein the shunt resistor is an embedded shunt resistor oriented vertically with respect to the first field effect coil and the second field effect coil, and wherein the first field effect coil and the second field effect coil are oriented horizontally with respect to the embedded shunt resistor.

20. The system of claim 19, further comprising a first layer of the printed circuit board, a second layer of the printed circuit board, a third layer of the printed circuit board, and a fourth layer of the printed circuit board, wherein the first layer of the printed circuit board and the fourth layer of the printed circuit board are electrically connected to the shunt resistor, and the second layer of the printed circuit board and the third layer of the printed circuit board are inductively coupled with the shunt resistor.
